(19) United States
(12) Patent Application Publication
(10) Pub. No.: US 2008/0023852 A1
(43) Pub. Date: Jan. 31, 2008

(54) Metal pad of mode dial and manufacturing method thereof

(76) Inventors: Yu-Cheng Huang, Hsinchu (TW); Tzu-Chih Lin, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/495,678

(22) Filed: Jul. 31, 2006

(51) Int. Cl. H01L 23/48

(52) U.S. Cl. 257/781

(57) ABSTRACT

A metal pad of mode dial and a manufacturing method thereof, wherein the metal pad is disposed on a substrate and the metal pad comprises at least one metal base pad and at least one conductive foil layer. The conductive foil layer is fixed on the metal base pad in an attached way instead of plating with gold on the metal base pad to reduce production costs so as to prevent oxidization of the metal base pad.

### BACKGROUND OF THE INVENTION

1. Field of the Invention

The present invention relates to a metal pad of a mode dial and a manufacturing method thereof, and more particularly to a metal pad of a mode dial is applied to electronic devices such as digital cameras, mobile phones, digital video camera, etc., and a manufacturing method thereof.

2. Description of the Prior Art

Recently with the rapidly development of science and technology, a large number of electronic devices such as digital cameras, mobile phones, and digital video camera, etc. are common in our daily life. Due to intensive competition in the market, hence, how to not only satisfy customers' demands but also reduce production costs are the important objectives.

Due to functions of the electronic devices are progressing, the internal electronic signals are more and more complicated. However, in order to prevent oxidization of the metal pads disposed on the circuit board to influence the electronic signals during the electronic signals are transmitting, the important metal pads are electroplated a layer of metal thin film thereon.

During the manufacturing process of electroplating with gold of the prior art, all metal base pads disposed on the circuit board need to be electroplated but a part of metal base pads. Hence, that is to relatively increase costs of manufacturing due to gold price has gone up.

The inventor of the present invention recognizes the above shortage should be corrected and special effort has been paid to research this field. The present invention is presented with reasonable design and good effect to resolve the above problems.

### SUMMARY OF THE INVENTION

It is a primary object of the present invention to provide a metal pad of a mode dial and a manufacturing method thereof to fix a conductive foil layer on a metal base pad in an attached way instead of plating with gold on the metal base pad to reduce production costs so as to prevent oxidization of the metal base pad.

For achieving the objectives stated above, the metal pad of a mode dial is disposed on a substrate and comprises at least one metal base pad is disposed on the substrate, and at least one conductive foil layer is fixed on the metal base pad in an attached way.

For achieving the objectives stated above, the manufacturing method of the metal pad of a mode dial comprises the steps of: providing a substrate, and the substrate has at least one metal base pad thereon; providing a foil patch, and the foil patch has at least one conductive foil layer thereon; positioning the foil patch on the substrate by positioning components; fixing the conductive foil layer on the metal base pad in an attached way; and retaining the conductive foil layer and ripping the foil patch.

For achieving the objectives stated above, another manufacturing method of a metal pad of a mode dial comprises the steps of: providing a substrate, and the substrate has at least one metal base pad thereon; providing a conductive foil layer; and fixing the conductive foil layer on the metal base pad in an attached way by a packing machine.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The above and further advantages of this invention may be better understood by referring to the following description, taken in conjunction with the accompanying drawings, in which:

FIG. 1 is a plane exploded view of a first embodiment of a metal pad of a mode dial according to the present invention;

FIG. 2 is a flowchart of the first embodiment of a manufacturing method of a metal pad of a mode dial according to the present invention;

FIG. 3 is a plane exploded view of a second embodiment of a metal base pad and a conductive foil layer according to the present invention;

FIG. 4 is a flowchart of the second embodiment of a manufacturing method of a metal pad of a mode dial according to the present invention; and

FIG. 5 is a cross-sectional schematic view of a metal pad of a mode dial according to the present invention.

The drawings will be described further in connection with the following detailed description of the present invention.

### DETAILED DESCRIPTION OF THE PREFERRED EMBODIMENTS

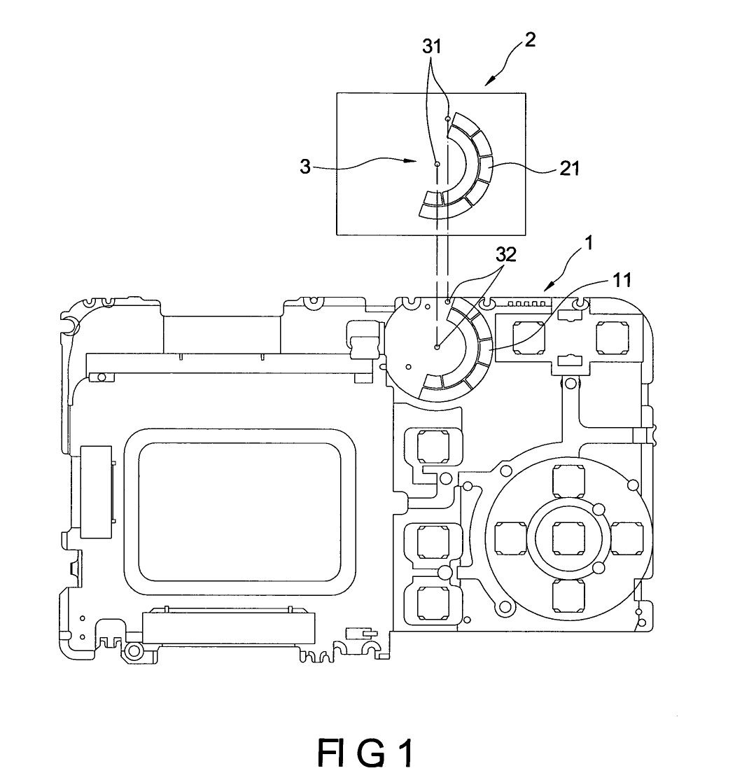

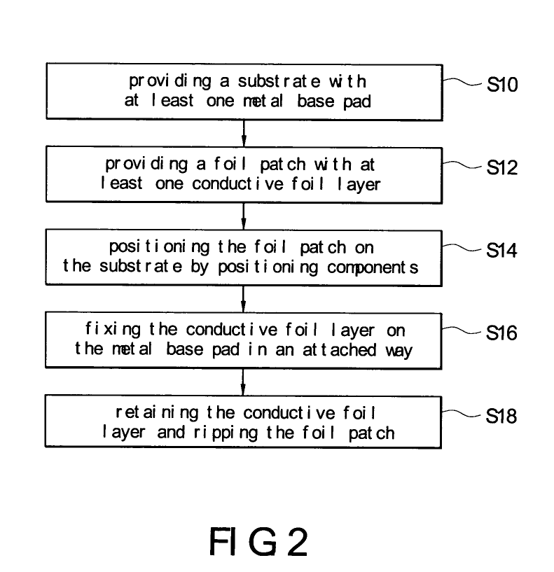

References are made to FIG. 1 and FIG. 2. A manufacturing method of a metal pad of a mode dial comprises the steps of:

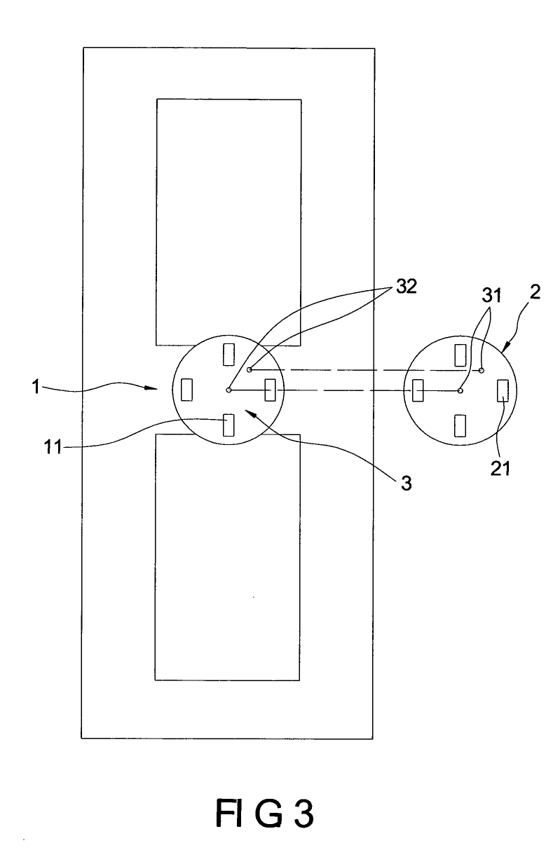

Firstly, providing a substrate 1 and the substrate 1 has a plurality of metal base pads 11 thereon (S10). The substrate 1 is a circuit board, the metal base pads 11 are curved-shaped and metal material composed of cooper, and disposed at intervals on the substrate 1. Besides, the substrate 1 is also a non-conductive insulating material, each of the metal base pads 11 is also zinc, nickel, tin, or combination of above-mentioned metals, or cooper alloy, zinc alloy, nickel alloy, tin alloy, or combination of above-mentioned alloys. Moreover, the metal base pads 11 are also square-shaped, rectangular-shaped (show in FIG. 3), polygonal-shaped, or other-shaped.

And next, providing a foil patch 2 and the foil patch 2 has a plurality of conductive foil layers 21 thereon (S12). The foil patch 2 is a square-shaped, flexible material. The conductive foil layers 21 are curved-shaped and metal material composed of gold, and disposed at intervals on the foil patch 2. Besides, the conductive foil layers 21 are also squared-shaped, rectangular-shaped (shown in FIG. 3), polygonal-shaped, or other-shaped, each of the conductive foil layers 21 is also silver, chromium, zinc, cooper, nickel, cadmium, tin, or combination of above-mentioned metals. Moreover, the foil patch 2 is also curved-shaped, rectangular-shaped, or polygonal-shaped.

And next, positioning the foil patch 2 on the substrate 1 by positioning components 3 (S14). The positioning components 3 have a plurality of positioning holes 31 and a plurality of pillars 32. The positioning holes 31 are correspondingly disposed to the foil patch 2 and the positioning pillars are correspondingly disposed to the substrate 1, and the positioning holes 31 and the positioning pillars 32 are mutually matched to position the foil patch 2 on the substrate 1.

And next, fixing the conductive foil layers 21 on the metal base pads 11 in an attached way (S16).

Finally, retaining the conductive foil layers 21 and ripping the foil patch 2 (S18).

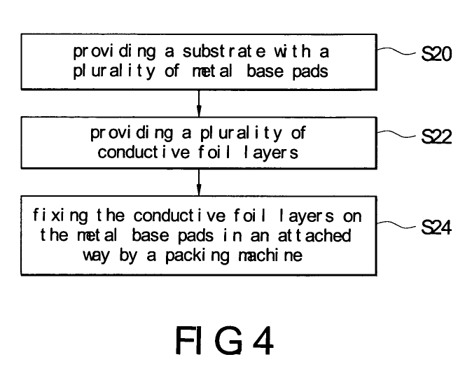

Reference is made to FIG. 4, which is a flowchart of the second embodiment of a manufacturing method of a metal pad of a mode dial according to the present invention, comprises the steps of:

Firstly, providing a substrate and the substrate has a plurality of metal base pad thereon (S20).

And next, providing a plurality of conductive foil layers (S22).

Finally, fixing the conductive foil layers on the metal base pad in an attached way by a packing machine (S24).

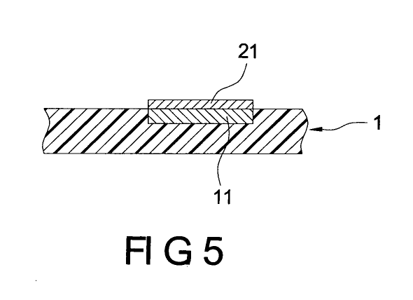

Reference is made to FIG. 5, the above-mentioned manufacturing method provides a metal pad of a mode dial is disposed on the substrate 1, the metal pad comprises metal base pads 11 are disposed on the substrate 1 and conductive foil layers 21 are fixed on the metal base pads 11 in an attached way.

The metal pad of mode dial and the manufacturing method thereof, the conductive foil layers 21 are fixed on the metal base pad 11 in an attached way instead of plating with gold on the metal base pad 11 to reduce production costs of plating with gold so as to prevent oxidization of the metal base pad 11.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A metal pad of a mode dial disposed on a substrate, comprising:
at least one metal base pad disposed on the substrate; and
at least one conductive foil layer attached on the metal base pad.

2. The metal pad of the mode dial as claimed in claim 1, wherein the substrate is a circuit board.

3. The metal pad of the mode dial as claimed in claim 1, wherein the substrate is a non-conductive insulating material.

4. The metal pad of the mode dial as claimed in claim 1, wherein the metal base pad is curve-shaped, square-shaped, rectangular-shaped, or polygonal-shaped.

5. The metal pad of the mode dial as claimed in claim 1, wherein the metal base pad is a metal material composed of copper, zinc, nickel, tin, or combination of above-mentioned metals.

6. The metal pad of the mode dial as claimed in claim 1, wherein the metal base pad is a metal material composed of cooper alloy, zinc alloy, nickel alloy, tin alloy, or combination of above-mentioned alloys.

7. The metal pad of the mode dial as claimed in claim 1, wherein the conductive foil layer is curve-shaped, square-shaped, rectangular-shaped, or polygonal-shaped.

8. The metal pad of the mode dial as claimed in claim 1, wherein the conductive foil layer is a metal material composed of gold, silver, chromium, zinc, copper, nickel, cadmium, tin, or combination of above-mentioned metals.

9. A manufacturing method of a metal pad of a mode dial, comprising the steps of:
providing a substrate, and the substrate having at least one metal base pad thereon;
providing a foil patch, and the foil patch having at least one conductive foil layer thereon;
positioning the foil patch on the substrate by positioning components;
attaching the conductive foil layer on the metal base pad; and
retaining the conductive foil layer and ripping the foil patch.

10. The manufacturing method of the metal pad of the mode dial as claimed in claim 9, wherein the positioning components have a plurality of positioning holes and a plurality of positioning pillars; the positioning holes are disposed on one of the substrate and the foil patch both, the positioning pillars are disposed on another one of the substrate and the foil patch bath, and the positioning holes and the positioning pillars are mutually matched.

11. The manufacturing method of the metal pad of the mode dial as claimed in claim 9, wherein the foil patch is a flexible material.

12. The manufacturing method of the metal pad of the mode dial as claimed in claim 9, wherein the foil patch is curve-shaped, square-shaped, rectangular-shaped, or polygonal-shaped.

13. A manufacturing method of a metal pad of a mode dial, comprising the steps of:
providing a substrate, and the substrate having at least one metal base pad thereon;
providing a conductive foil layer; and
attaching the conductive foil layer on the metal base pad by a packing machine.
